(19) United States
(12) Patent Application Publication
(10) Pub. No.: US 2025/0037977 A1
(43) Pub. Date: Jan. 30, 2025

(54) APPARATUS AND METHOD FOR PLASMA PROCESSING

(71) Applicant: Tokyo Electron Limited, Tokyo (JP)

(72) Inventor: Barton Lane, Austin, TX (US)

(21) Appl. No.: 18/359,783

(22) Filed: Jul. 26, 2023

(51) Int. Cl. H01J 37/32

(52) U.S. Cl. CPC H01J 37/32458; H01J 37/3222; H01J 37/32238; H01J 37/32449; H01J 37/32651; H01J 37/32669; H01J 37/32715

(57) ABSTRACT

An apparatus for plasma processing a substrate, where the apparatus includes a plasma processing chamber having a ceiling including a central conductive cover surrounded by a dielectric window, the conductive cover being wider than the substrate; a substrate holder configured to hold the substrate in the chamber, a backside of the substrate being aligned to be inside a hold area of a horizontal top surface of the holder, the hold area being an area under the conductive cover; disposed over the dielectric window, an antenna configured to couple AC electromagnetic (EM) power from an AC EM signal to plasma in the chamber, the AC EM power being absorbed in a heating zone located within a depth directly below the dielectric window; and a magnet configured to generate a DC magnetic field in the chamber, the central flux tube being a magnetic flux tube intercepting the hold area.

### TECHNICAL FIELD

The present invention relates generally to apparatus and method for semiconductor device processing and, in particular embodiments, to apparatus and method for plasma processing.

### BACKGROUND

Fabricating a semiconductor integrated circuit (IC) comprises integrating a network of electronic components in a monolithic structure. A two-dimensional (2D) array of IC units is formed on each substrate of a batch of substrates processed through a series of patterning levels. At each level, layers of diverse materials are deposited and patterned using lithography and etch techniques that transfer a pattern of actinic radiation to targeted layers. Enabled by advances in technology, a new IC node is introduced about every two years, where the component density has been doubled to reduce the unit cost of ICs and, at the same time, enhance speed and functionality. The density is doubled by shrinking feature sizes and using three dimensional (3D) devices, a combination that leads to fabricating structures with high aspect ratios. Many of the deposition and etch steps in forming 3D devices (e.g., nanosheet transistors and vertical NAND (V-NAND) memory) are plasma processes, some of which, such as high aspect ratio contact (HARC) etch, may need special plasma properties like a highly collimated ion flux toward the substrate. Thus, plasma technology is now challenged to not only pattern nanoscale features with high aspect ratio and smooth vertical sidewalls but also provide the stringent process control needed in volume manufacturing. To meet this challenge, innovations in plasma apparatus and methods are desired that provide enhanced flexibility and control over plasma properties such as plasma density, electron temperature, radical flux, ion flux, and ion angle and energy distributions.

### SUMMARY

An apparatus for plasma processing a substrate, where the apparatus includes a plasma processing chamber having a ceiling including a central conductive cover surrounded by a dielectric window, the conductive cover being wider than the substrate; a substrate holder configured to hold the substrate in the chamber, a backside of the substrate being aligned to be inside a hold area of a horizontal top surface of the holder, the hold area being an area under the conductive cover; disposed over the dielectric window, an antenna configured to couple alternating current (AC) electromagnetic (EM) power from an AC EM signal to plasma in the chamber, the AC EM power being absorbed in a heating zone located within a depth directly below the dielectric window; and a magnet configured to generate a DC magnetic field in the chamber, where a width of a central flux tube at the ceiling is less than or equal to a width of the conductive cover, the central flux tube being a magnetic flux tube intercepting the hold area.

An apparatus for plasma processing a substrate, where the apparatus includes a plasma processing chamber having a ceiling including a central conductive cover surrounded by a dielectric window, the conductive cover being wider than the substrate; a substrate holder configured to hold the substrate in the chamber, a backside of the substrate being aligned to be inside a hold area of a horizontal top surface of the holder, the hold area being an area under the conductive cover; disposed over the dielectric window, an antenna configured to produce AC electric and magnetic fields in a plasma generated in the chamber, the AC electric field being in a second region laterally separated from a first region of the chamber, the first region being a central tube bounded by and including the hold area at the bottom and bounded by the conductive cover at the top; and a magnet configured to generate a DC magnetic field in the chamber, where, between the substrate holder and the ceiling, a maximum width of a central flux tube is less than or equal to a width of the conductive cover, the central flux tube being a magnetic flux tube intercepting the hold area.

A method for plasma processing, where the method includes holding a substrate on a horizontal top surface of a substrate holder in a plasma processing chamber having a ceiling including a central conductive cover surrounded by a dielectric window, the conductive cover being wider than the substrate; prior to holding the substrate, aligning its backside to be inside a hold area of the top surface of the holder, the hold area being an area under the conductive cover; generating plasma in the chamber using power from AC electromagnetic (EM) fields produced in the chamber by an antenna disposed over the dielectric window, the antenna being coupled to an AC EM power source; applying a DC magnetic field with a magnet configured to generate the DC magnetic field in the chamber, where, between the substrate holder and the ceiling, a maximum width of a central flux tube is less than or equal to a width of the conductive cover, the central flux tube being a magnetic flux tube intercepting the hold area; and exposing the substrate to plasma for a process duration time to process the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic of various regions of a gas discharge proximate a substrate in a plasma processing chamber;

FIG. 2 illustrates a cross-sectional view of an apparatus for plasma processing a substrate, in accordance with an embodiment; and

FIG. 3 illustrates a flow chart summarizing a method for plasma processing, in accordance with an embodiment.

### DETAILED DESCRIPTION OF ILLUSTRATIVE EMBODIMENTS

This disclosure describes embodiments of plasma processing apparatus and methods to process a substrate using a flux of ions propagating from a plasma and impinging on an exposed surface of the substrate, where a spread in an ion angle distribution of the ions arriving at a major surface of the substrate has been reduced to provide a highly collimated vertical ion flux colliding with the substrate. (Note that, for specificity, the direction normal to the major surface of the substrate is selected as the vertical direction.) Providing an ion flux with such vertically directed kinetic energy is advantageous for performing anisotropic plasma processes, for example, a HARC etch process that may be used to form a high aspect ratio vertical feature. Examples of vertical features in an IC include silicon fins, transistor metal gates wrapping around the fins, via and contact holes in interlayer dielectric (ILD) layers, and stacked gates of V-NAND memory.

It is desirable to have the incoming ions impinge on a substantially horizontal portion of the exposed surface (e.g., the bottom of a partially etched feature) instead of a substantially vertical portion of the exposed surface (e.g., the sidewalls of a partially etched feature) in order to obtain smooth vertical sidewalls. The more the ion angle deviates from zero degree (zero degree being defined as the vertically downward direction), the higher the probability that the ion collides with the sidewall of a vertical feature. Energetic ions colliding with the sidewall may roughen the sidewall surface as well as result in an undesired non-vertical etch profile, for example, an undercut or a sloped sidewall. Furthermore, highly collimated ion flux is needed to provide a sufficient number of ions reaching the bottom of very high aspect ratio features to process the surface there. The ions lose energy in inelastic collisions with the sidewall. Typically, as the processing progresses, the aspect ratio of the feature increases. The increased aspect ratio reduces the fraction of sufficiently energetic ions reaching the bottom of the feature, thus slowing down the rate at which the processing may progress there. Thus, it is advantageous to have a distribution of ions such that, by the time the ions arrive at the surface of the substrate, their kinetic energy is concentrated within an angle as close to vertical as possible. In other words, if the average ionic kinetic energy is considered to be a sum of a directed component and a random component, where the random component is the average kinetic energy in an isotropic velocity distribution of ions then it is desirable to have the random component as small a fraction of the sum as possible.

The plasma processing, referred to in this disclosure, is “direct” plasma processing, where plasma is generated by ionizing gas at low pressure in the same chamber where the substrate is processed. In direct plasma processing, the plasma is in close proximity directly above the substrate. Thus, the ion angle distribution of interest is that of positively charged ions located in a plasma sheath adjacent to the surface of the substrate, when it is being exposed to the plasma.

Steady state fluxes of ions and free electrons to the substrate are sustained during the plasma processing with ion-electron pairs generated in a gas discharge, where a charge-neutral gas is ionized using electromagnetic (EM) energy. The ionization process creates an equal number of positively charged ions and negatively charged free electrons, resulting in a charge-neutral bulk plasma. However, a plasma sheath, which is a positively charged peripheral region of high electric field forms between a boundary (which is the substrate in this instance) and a charge-neutral plasma region. The sheath results from a large ratio of ion mass to electron mass that results in much higher velocities, hence a much higher effective temperature for electrons (Tₑ) relative to ions with the same kinetic energy. The higher Tₑ gives higher diffusivity to the free electrons of the ion-electron pairs generated by the ionization process. Thus, during an initial transient, a rapid out-diffusion of electrons occurs from the plasma to the substrate, which charges the substrate negatively. This negative charge reduces the electric potential at the surface of the substrate, which repels electrons and attracts ions to the substrate. The transient electron and ion fluxes settle to a steady state, where the electric field is progressively increasing from zero in the charge-neutral plasma to a very high value at the surface of the substrate. It is noted that the steady state may not be a stationary state, where the various particle fluxes are time independent. Indeed, in most instances, the plasma, being sustained by continuous wave (CW) AC EM power or pulsed AC EM power (i.e., periodic bursts of AC EM power), settles to a steady state that includes fluxes that are periodic functions of time.

Generally, it is valid to consider that ions in a sufficiently low-pressure chamber have a negligible probability of colliding with another particle (e.g., a neutral particle) when accelerating through the high electric field of the plasma sheath before impinging on the substrate. In the absence of collisions, the entire drop in electric potential across the sheath is a gain in kinetic energy of ions directed toward the substrate. Furthermore, the number of ions in the sheath is conserved; hence, the ion flux is constant, although the ion drift velocity, vᵢₒₙ, defined as the mean of the ion velocity distribution, increases toward the substrate. The ion flux being a product of vᵢₒₙ and ion density, the constraint of uniform ion flux forces an ion density profile, where ion density reduces toward the substrate. It follows that the constraint establishes a mathematical relation between the ion density and electric potential profiles.

Since the electric field increases monotonically toward the substrate (as explained above), by Gauss' law in electrostatics, the net space charge density in this region is positive, despite a decreasing number density of the positively charged ions, thus forcing the electron density to reduce even faster to provide the positive space charge required by electrostatics.

The electron density is also related to the electric potential. Unlike the ions, which have a non-Maxwellian distribution function with a directed component of kinetic energy much larger than the random component, the electron distribution is well approximated by a Maxwellian function with Tₑ as a parameter. A Maxwellian function is directly proportional to exp (−E/k_{B}Tₑ). Here, E denotes the electron's energy and k_{B} is Boltzmann's constant. Noting that E includes potential energy, and since potential energy is a product of charge and electric potential, the number density of negatively charged electrons reduces exponentially with reducing electric potential. As explained above, the surface of the substrate is negatively charged. This negative charge causes the electric potential to reduce monotonically toward the substrate, and the electron density to drop exponentially with the reducing electric potential. The profiles for electric potential, along with the ion and electron densities and velocities evolve self-consistently to settle to the final profiles of the steady state of the sheath in a short time.

As described above, the steady state of the sheath is characterized by collision-free transport of ions, the non-Maxwellian ion distribution, the Maxwellian electron distribution, a uniform ion flux, and positive space charge density. As known to persons skilled in the art, for an initial transient to stabilize to such a steady state, the drift velocity of ions entering the sheath has to exceed a minimum value, called the Bohm velocity, v_{B}, defined as v_{B}=(k_{B}Tₑ/Mᵢₒₙ)^{1/2}, where Mᵢₒₙ is a mass of the ion. (Here, for simplicity, we assumed each ion to have one unit of electronic charge.) After entering the sheath, at sufficiently low pressures (i.e., long mean free path) and high electric fields (i.e., short transit time), the ions accelerate through the sheath without suffering randomizing collisions. With vᵢₒₙ increasing continuously toward the substrate, Mᵢₒₙvᵢₒₙ²/2≥k_{B}Tₑ/2 is satisfied everywhere inside the sheath. This inequality, known as the Bohm criterion, is used here to define the sheath, with the sheath edge being the location, where vᵢₒₙ=v_{B}. The mean velocity or drift velocity, vᵢₒₙ, represents the directed component of the ion kinetic energy (directed toward the substrate), whereas the random component of the kinetic energy is represented by a thermal velocity of ions, v_{th_ion}, where v_{th_ion}=(k_{B}Tᵢₒₙ/Mᵢₒₙ)^{1/2}, and Tᵢₒₙ is the ion effective temperature. Because an ion is massive compared to a free electron, Tₑ>>Tᵢₒₙ, it follows from the definition of the Bohm velocity, that v_{B}>>v_{th_ion}. As explained in further detail below, this necessitates a quasi-neutral pre-sheath region with sufficient positive charge to establish an electric field that serves to raise the drift velocity to v_{B}.

As mentioned above, the source of ions and free electrons needed to sustain their steady state fluxes to the substrate is the bulk plasma. While the individual concentrations of ions and free electrons may be high in bulk plasma, the net charge density and, hence, the electric field are often negligibly low. Generally, the higher ion density and negligible electric field result in ions having, on the average, a relatively low kinetic energy, which gets distributed isotropically as ions collide with neighboring particles. Such a velocity distribution is modeled as a Maxwellian distribution with a mean ion velocity, vᵢₒₙ, much less than the ion thermal velocity, v_{th_ion}. In contrast, the sheath has high net positive charge density, high vertical electric field, and high directed ionic kinetic energy, i.e., the drift velocity vᵢₒₙ far exceeds v_{th_ion} and is directed parallel to the electric field. Indeed, as described above, the sheath is characterized by the ion drift velocity equaling or exceeding the Bohm velocity (i.e., vᵢₒₙ≥v_{B}). The ions emerge from the charge-neutral region with vᵢₒₙ≈0 but, by the time they arrive at the sheath edge, vᵢₒₙ=v_{B}. Clearly, the velocity distribution has evolved from an isotropic Maxwellian distribution to an anisotropic distribution with a large vertically directed drift velocity, directed toward the substrate. This transition is accomplished in a positively charged quasi-neutral region (referred to as the pre-sheath region), where a small imbalance between the ion and free electron densities establishes vertical electric fields that accelerate ions to raise vᵢₒₙ from near-zero at the edge of the bulk plasma to v_{B} at the edge of the sheath.

In what has been described thus far, after the initial transient, the gas discharge has stabilized to a steady state having potential and electric field profiles that are stationary along the vertical direction, since they are defined by static constraints. For example, if the EM energy is sustaining a purely inductively coupled plasma (ICP) then the induced AC electric field is in a horizontal plane in the plasma. Hence, along the vertical direction, the potential and electric field profiles are adequately described by electrostatics. The constraints on the electrostatic equations include a negatively charged DC equipotential surface of the substrate at one end and a charge-neutral equipotential surface of the bulk plasma at a fixed location on the opposite end. The region between the two equipotential planes includes the collision-free sheath (defined by the Bohm criterion) and the pre-sheath region, where ions in the pre-sheath region may collide a few times with neutrals during transit, as described further below. In the above description, in the vertical direction, the region between the two equipotential planes has profiles of charge density, potential, and electric field and a length dimension that are all stationary. However, even if the AC electric field induced by the EM power coupled to the plasma were parallel to the particle fluxes (e.g., the horizontal sheath of the ICP formed near the sidewall of the chamber or the vertical sheath of a capacitively coupled plasma (CCP) formed near the surface of the substrate), the electrostatic description may be used in a quasi-static approximation. In the quasi-static approximation, the previously stationary vertical profiles and lengths (e.g., of the sheath and pre-sheath regions) become time dependent. For example, the length and the potential drop between the equipotential planes at the two ends may oscillate in tandem with the applied AC electric field.

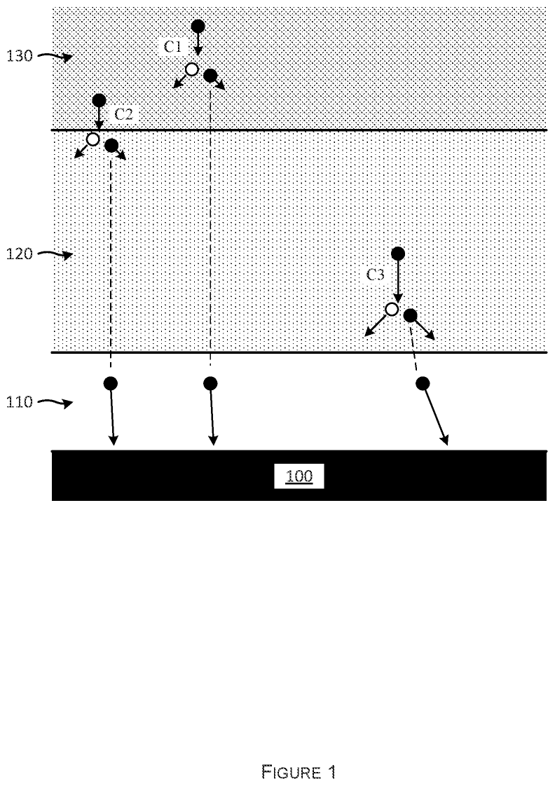

The details of the static (or quasi-static) fields are described now with reference to FIG. 1. FIG. 1 illustrates a schematic of three regions of monotonically progressing electric field directed toward the negatively charged surface of the substrate 100. Closest to the substrate 100 is the sheath 110. As described above, the sheath 110 is a region of high electric field and net positive charge density. A quasi-neutral transition region, referred to as a pre-sheath 120, occurs between the sheath 110 and a charge-neutral bulk plasma 130 located farthest from the substrate 100 in FIG. 1. As explained below, the angular distribution of the kinetic energy of ions in the ion flux incident on the surface of the substrate 100 is determined primarily by collisions between ions and neutral particles in the pre-sheath 120.

As mentioned above, the ion drift velocity, vi, directed vertically toward the substrate 100, is small in the bulk plasma 130. The low drift velocity is a consequence of several factors, including low ion mobility and low electric field in the charge-neutral bulk plasma 130. The low mobility is not only due to the high ion mass but also due to a large number of scattering events experienced by ions transiting through the bulk plasma 130. Generally, the bulk plasma region 130 extends over a length many times the length of an ion mean free path, resulting in many collisions (such as the collision C1 in FIG. 1) which scatter the ions in random directions. Thus, the ions emerge from the bulk plasma 130 and enter the pre-sheath 120 with a ratio of vᵢₒₙ/v_{B}≈0. In FIG. 1, we show a demarcated boundary between pre-sheath 120 and the bulk plasma 130. However, it is understood that the boundary is not sharply defined. Generally, the length of the pre-sheath is approximately a few ion mean free paths. The acceleration from the low directed velocity (vᵢₒₙ/v_{B}≈0) in the bulk plasma 130 to the full Bohm velocity (vᵢₒₙ/v_{B}=1) takes place in the pre-sheath 120.

By definition, everywhere in the sheath 110, vᵢₒₙ≥v_{B}. As the ions approach the surface, vᵢₒₙ>>v_{B}, the electric field and vᵢₒₙ attaining their highest values adjacent to the surface. At the edge of the sheath 110 at the opposite end, vᵢₒₙ=v_{B}. However, for the ions emerging out of the bulk plasma 130, where the electric field is negligibly small, vᵢₒₙ<<v_{B}. Thus, as illustrated schematically in FIG. 1, the pre-sheath 120 has formed between the charge-neutral bulk plasma 130 and the sheath 110, where an electric field encroaches in from the sheath edge and drives vᵢₒₙ up from near-zero in the charge-neutral bulk plasma to v_{B} at the sheath edge. The pre-sheath 120 has an electric potential drop of about k_{B}Tₑ/(2|q|) and a low positive charge density, consistent with Gauss' law. Here, q denotes the electronic charge. The positive charge density is small enough to consider the pre-sheath to be quasi-neutral, which implies that the ion and electron densities are roughly equal. As described above, the length of the pre-sheath is a few ion mean free paths. Thus, during the time that each of the ions is accelerated in the pre-sheath for the mean velocity to attain the full Bohm velocity (vᵢₒₙ/v_{B}=1), the ions, on the average, undergo several collisions.

Several collision events are shown schematically in FIG. 1, where the solid circles represent ions and open circles represent neutral particles. An arrow attached to each particle represents its momentum vector. In each of the three collisions illustrated in FIG. 1, an incoming ion, moving in a vertically downward direction (zero degree), collides with a slowly moving neutral particle, and is scattered in a different direction. Since the initial momenta of the colliding particles are uncorrelated, part of the momentum parallel to the accelerating electric field acquired by the ions between successive collisions gets redistributed isotropically by collisions, thus increasing the spread in the angle distribution of ion kinetic energy. However, collisions that occur at a location where the ion drift velocity, vᵢₒₙ, is small compared to the ion thermal velocity (v_{th_ion}), would have very little effect on the ion angle distribution of interest, which is the ion angle distribution of the ions impinging on the substrate.

Referring to FIG. 1, the two collisions, C1 and C2, shown on the left side are in the bulk plasma 130 and in a region where ions from the bulk plasma 130 have barely entered the pre-sheath 120, respectively. At these locations, vᵢₒₙ<<v_{Bohm}: Almost all of the total kinetic energy of the ions is distributed isotropically and there is very little excess directed component of kinetic energy acquired from the electric field available to be redistributed isotropically. In contrast, the collision event, C3, shown on the right side, occurs at a location deeper into the pre-sheath 120, where the ions have acquired directed kinetic energy from the electric potential drop to increase vᵢₒₙ≈v_{B}. Note that, as explained above, v_{B} is much greater than the thermal velocity of ions, v_{th_ion} because the electron temperature is typically on the order of a few eV while the ion thermal temperature is on the order of 1/20 eV or less. Thus, it is the collisions with the more energetic ions in the pre-sheath 120 (e.g., the collision event, C3) that transfer a much larger amount of energy to the isotropic random component of kinetic energy. Furthermore, since vᵢₒₙ≈v_{B} and v_{B}=(k_{B}Tₑ/Mᵢₒₙ)^{1/2}, the random component of kinetic energy of ions entering the sheath is expected to be directly proportional to Tₑ^{1/2}. Progressing further toward the substrate 100, inside the sheath 110, the ion transport becomes ballistic and, in the absence of collisions, no further energy is added to the random component of the kinetic energy of ions. The electric potential drop in the sheath 110, which is almost the total potential drop between the bulk plasma 130 and the substrate 100 (except for a small drop in the pre-sheath 120) largely determines the vertical component of a final velocity with which ions strike the surface of the substrate 100. Thus, as illustrated in FIG. 1, the spread in the ion angle distribution, which depends on a ratio of the random component to the directed component of the kinetic energy of ions incident on the surface of the substrate 100, is also expected to be directly proportional to Tₑ^{1/2}. Accordingly, the spread in the ion angle distribution may be reduced by reducing Tₑ. The present disclosure describes embodiments of apparatus and method for plasma processing that lower the electron temperature in the region above the substrate in order to reduce the ion angular spread.

While it is desirable to reduce Tₑ of the plasma above the substrate 100 in order to achieve a more collimated vertical ion flux incident on the substrate 100, a high Tₑ is needed for generating ions and radicals efficiently to sustain plasma having a desired density of ions in the plasma processing chamber. The invented apparatus and method provide the advantage of generating, in the plasma processing chamber, a plasma that has an electron temperature Tₑ₁ inside a first region above the area where the substrate is held, and an electron temperature Tₑ₂ inside an annular second region around the first plasma, where Tₑ₂>Tₑ₁. The charge-neutral and quasi-neutral plasma in the first region, referred to as a first plasma, is at an electron temperature Tₑ₁, and that in the second region, referred to as a second plasma, is at an electron temperature Tₑ₂. The second plasma may be viewed as a “heated” annular region generating the ions, radicals, and free electrons that sustain plasma in the chamber. As explained further below, a DC magnetic field may be used to restrain free electrons at the higher energy end of the distribution from rapidly exiting the second plasma, thus creating the “cooler” first plasma with a magnetically filtered distribution of lower energy electrons outside the first plasma (which is the annular heated plasma).

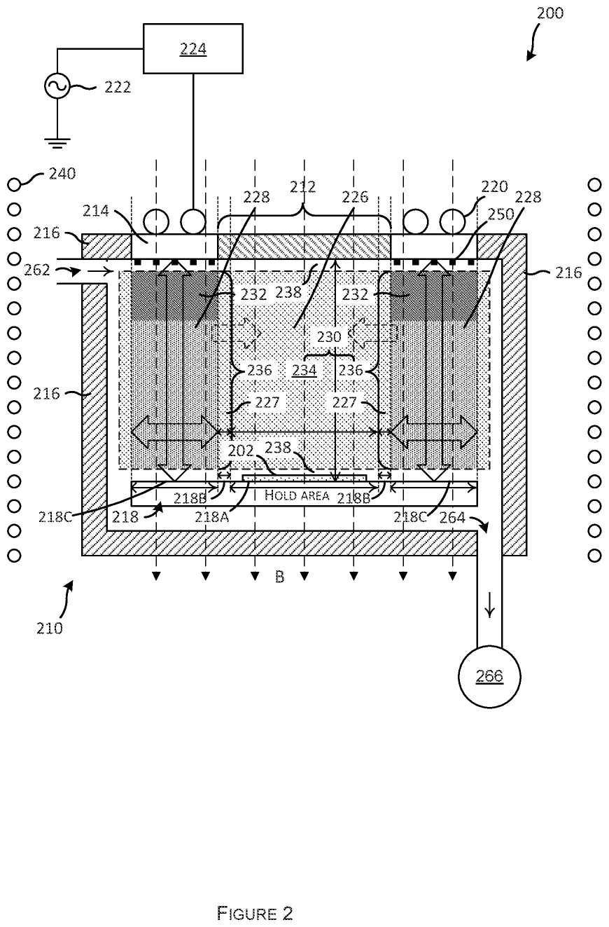

FIG. 2 illustrates a cross-sectional view of an example apparatus 200 for plasma processing a substrate 202 in a plasma processing chamber 210 configured to generate plasma having the dual temperature characteristic mentioned above. The chamber 210 in FIG. 2, when operated to sustain plasma, is configured in an inductively coupled plasma (ICP) mode. In the ICP mode, an AC magnetic field generated outside the chamber 210 is coupled to plasma inside the chamber 210. The coupling, which is similar to magnetic field coupling from a primary coil to a secondary coil in a transformer, generates an AC magnetic field in the plasma. Consistent with EM theory, the AC magnetic field in the plasma induces an AC electric field (and current) there. The induced AC electric field transfers energy from the field to the motion of charged particles (i.e., ions and free electrons, but mostly to the free electrons) in the plasma, thus coupling EM power from an external source to plasma. This process is often referred to as “heating” because, in the charge-neutral plasma, randomizing collisions distribute the acquired excess energy isotropically, thus creating a non-equilibrium Maxwellian distribution electrons, which is described by an electron temperature much higher than the ambient temperature.

As known to persons skilled in the art, external AC magnetic fields penetrate through dielectric material but may be blocked by a conductive wall. This property of EM fields is applied to embodiments of the plasma processing apparatus (described in this disclosure) to engineer a toroidal heating zone that is spaced radially away from a central hold area designated for holding a substrate during processing. A heating zone refers to a portion of the plasma inside the chamber, where AC EM power from the induced EM fields is transferred to charged particles in the plasma. A localized heating zone may be achieved, for example, by generating the external EM fields above the chamber and configuring a top cover or ceiling of the chamber to block the AC magnetic field from passing through a central portion of the ceiling that covers the entire hold area. An example configuration is described herein with reference to FIG. 2.

As illustrated in FIG. 2, the ceiling of the plasma processing chamber 210 comprises a central conductive cover 212 surrounded by a dielectric window 214. The rest of the boundary walls 216 of the chamber 210, typically, comprises a conductive material. That includes remaining portions of the ceiling, a sidewall, and a bottomwall. A substrate holder 218, disposed in a bottom portion of the chamber 210, may be, for example, an electrostatic chuck (ESC) configured to hold the substrate 202 on an insulating top surface of the substrate holder 218. In the example illustrated in FIG. 2, the substrate holder 218 is positioned symmetrically around a central axis of the chamber 210, with the disk-shaped top surface of the substrate holder 218 extending radially to include an area below the combined area of the central conductive cover 212 and the dielectric window 214.

In the example embodiment of the apparatus 200 in FIG. 2, a central portion of a horizontal top surface of the substrate holder 218 (indicated by a horizontal double arrow adjacent below the top surface) has been designated as the hold area 218A. Note that the entire hold area 218A is vertically under the conductive cover 212 in the ceiling above. Furthermore, in this embodiment, a width of the hold area 218A is less than a width of the conductive cover 212. The conductive cover 212 extends to cover a slightly bigger area of the top surface of the substrate holder 218 than the area of the hold area 218A, as indicated by two double arrows on opposite ends of the double arrow indicating the hold area 218A in the middle. This is a first ring-shaped area of the top surface, referred to as a first ring 218B. The first ring 218B separates the hold area 218A from a second ring-shaped area of the top surface of the substrate holder 218. This second ring-shaped area, referred to as a second ring 218C, is vertically under the dielectric window 214. Thus, the top surface of the substrate holder 218 has three concentric circles that define the boundaries of three nested areas: a circular central area surrounded by two nested rings. The central circular area is the hold area 218A. The inner ring surrounding the central area is the first ring 218B contiguous with the hold area 218A, and the outer ring is the second ring 218C contiguous with the first ring 218B. Clearly, the second ring 218C is laterally spaced from the hold area 218A, the spacing being the first ring 218B.

The three nested areas of the top surface of the substrate holder 218 are floors of three respectively nested tubular regions of the chamber 210: a central tube and two nested annular tubes disposed contiguously around the central tube. The central tube, referred to here as a first region, has the hold area 218A as its floor. The first region extends upwards to intercept the ceiling at an area within the conductive cover 212, for example, the first region 226 of the chamber 210, illustrated in FIG. 2. The outer annular tube, referred to as here as a second region, has the second ring 218C as its floor and is disposed contiguously around the inner annular tube. The inner annular tube, referred to as here as a third region, has the first ring 218B as its floor and is disposed contiguously around the first region. The ceiling of the second region is the dielectric window 214, and the ceiling of the third region is a ring-shaped area of the conductive cover 212 filling the area between the ceiling of the first region and the ceiling of the second region (which is the dielectric window). Thus, the three nested areas of the top surface of the substrate holder 218 are mapped onto three respective nested areas of the ceiling of the chamber 210 by the three nested tubes of the chamber 210, where the central first region is laterally spaced from the annular second region, the third region being the annular tube filling the space between the second region from the first region. In the vertical direction, the three nested regions extend from the top surface of the substrate holder 218 below to the ceiling of the chamber 210 above.

As mentioned above, and explained in further detail below, the conductive cover 212 shields EM radiation, thereby forming a localized heating zone 232 (the zone where EM power is coupled to plasma to generate “hot” electrons) in a toroidal region below the dielectric window 214. According to the above description of the first, second, and third regions, the heating zone 232 is included in the second region. As explained above, a lower electron temperature is desired for the plasma above the hold area 218A, i.e., in the first region. The lateral extent of the third region being the lateral separation between the first region and the second region helps reduce the number of hot electrons entering the first region from the heating zone 232 and raising the electron temperature of plasma above the substrate.

As mentioned above, a magnet may be used to generate a DC magnetic field in the chamber 210 in order to lower the electron temperature in plasma above the substrate. As explained in further detail below, it is undesirable to generate the DC magnetic field to have magnetic field lines passing through the heating zone 232 and intercepting the substrate held over the hold area 218B. In other words, it is undesirable to generate the DC magnetic field such that a magnetic flux tube intercepting the hold area 218B to also intercept the heating zone. This may be achieved by ensuring that the magnetic flux tube intercepting the hold area 218B does not enter the second region. Indeed, the magnet may be configured by design to generate a DC magnetic field, where the magnetic flux tube intercepting the hold area 218B is within the first region. Then the lateral separation due to the third region would provide a margin for unavoidable random errors in design and manufacture of the plasma processing apparatus. These aspects of the invention are explained and illustrated by the example apparatus 200, where an idealized uniform vertical magnetic field B has been applied, as illustrated in FIG. 2. Persons skilled in the art may extend the descriptions and explanations to other embodiments.

Referring to FIG. 2, the first region 226 is laterally spaced from a second region 228 of the chamber 210, where the second region 228 is a vertical annular region around the first region 226 and below the dielectric window. A third region 227 is shown filling the space separating the first region 226 from the second region 228. The third region 227 is another vertical annular region laterally contiguous with the vertical annular second region 228 and the first region 226. In the vertical direction, the third region 227 is bounded between the first ring 218B at the bottom and, at the top, by a narrow ring-shaped portion of the conductive cover 212 vertically above the first ring 218B. The first region 226, the second region 228, and the third region 227 have the same height, indicated by a vertical double arrow and a pair of vertical double block arrows of equal length. The width of the first region 226 is same as the width of the hold area 218A, indicated by lateral double arrows of equal length. The width of the second region 228, indicated by a pair of lateral double block arrows, is same as that of the dielectric window 214. The lateral separation between the first region 226 and the second region 228, which is the width of the third region 227, is same as the width of the first ring 218B, as indicated by two pairs of lateral double arrows of equal length.

Prior to processing the substrate 202, its center is aligned to a center of the hold area 218A to position a backside of the substrate 202 inside the hold area 218A, when held by the substrate holder 218. Note that the hold area 218A is designated to be wider than the substrate 202, depending on an alignment error tolerance, as illustrated in FIG. 2. This excess width of the hold area 218A, along with a width of the first ring 218B ensures that the backside of the substrate 202 is spaced from the second ring 218C (the area vertically below the dielectric window 214) despite errors, for example, alignment error and errors in lateral dimensions of the conductive cover 212 and the dielectric window 214. The relevance of this geometrical arrangement to reducing Tₑ of the plasma vertically above the substrate 202 is explained in further detail below.

An antenna 220 is disposed outside the chamber 210 over the dielectric window 214. As illustrated schematically in FIG. 2, the antenna 220 may be coupled to a circuit comprising an EM power source 222 and an impedance matcher 224 to receive an AC EM signal supplying EM power. Typically, the AC EM signal is in a narrow band around a center frequency between 100 kHz and 10 GHz. The EM power source 222 is an AC power supply comprising an oscillator and a power amplifier. Additional circuitry, for example, a chopper circuit for generating pulsed AC EM signals may be included in the AC power supply. Depending on the operating frequency band, the EM power source 222 may comprise a radio frequency (RF) power supply or a microwave frequency power supply. The impedance matcher 224 may comprise a passive circuit of inductors and capacitors connected in a configuration designed to suppress reflections and transfer power efficiently from the EM power source 222 to a load impedance comprising the impedance of the antenna and the plasma in the chamber 210.

The antenna 220 may be configured to couple AC EM power inductively to plasma in the chamber 210, using AC EM power supplied by the AC EM signal from the EM power source 222. As explained above, in inductive coupling, the external AC magnetic field from the antenna 220 produces an AC magnetic field and an induced AC electric field in the plasma. In the example embodiment in FIG. 2, the antenna 220 is a conductor, shaped like a planar coil, where a central axis of the planar coil is same as a central axis of the dielectric window 214. In some embodiments, a variable capacitor may be connected to the antenna 220 to tune a resonant frequency of an equivalent parallel LC circuit model of the antenna 220 (L and C being an inductance and a capacitance of the model). In some other embodiments, the antenna 220 may be a resonant structure comprising, for example, a conductive unibody rigid structure having a plurality of spiral arms attached to a central conductor. The central conductor may be a central disk-shaped conductive plate, for example, the central conductive cover 212.

According to EM theory, the AC electric and magnetic fields in the plasma are oriented horizontally and orthogonal to each other, with the induced AC electric field at any location in the plasma pointing in a direction opposite to that of currents flowing in the conductors of the antenna 220 vertically above that location. The central conductive cover 212 blocks the magnetic field from the antenna 220 above the chamber 210, thus laterally confining the location of the induced AC electric field in the plasma to be vertically below the dielectric window 214. In the vertical direction, because of the skin effect, the EM fields decay exponentially with increasing depth from the dielectric window 214 with a characteristic length, referred to as skin depth. The skin depth depends on a conductivity of the plasma and the frequency of the AC EM fields. Thus, the location of the induced AC electric field in the plasma gets vertically confined to within a depth of about two skin depths below the dielectric window 214. As illustrated in FIG. 2, the heating zone 232 is a toroidal volume of plasma within a depth directly below the dielectric window 214, where the induced AC electric field is confined laterally and vertically, as described above. In various embodiments, the depth dimension of the heating zone 232 may be from about 1 mm to about 10 cm. A lateral width of the heating zone 232 is substantially same as that of the dielectric window 214, which may be from about 5 cm to about 55 cm.

The plasma 230 is the combined charge-neutral and quasi-neutral regions that have been generated in the chamber 210 using EM power from the antenna 220. As explained above, free electrons, being more mobile than ions, are preferentially accelerated by the AC electric field induced in the heating zone 232, and, with collisions, the free electrons reach a Maxwellian distribution with a high effective temperature. In some of the collisions with neutral gas particles, energetic free electrons may lose a portion of their kinetic energy to ionize the neutral particles, thus forming new electron-ion pairs.

A plasma sheath 238 is shown formed adjacent to the substrate 202, the substrate holder 218, the sidewall, and the ceiling of the chamber 210. A dashed line along a rectangular perimeter is used in FIG. 2 to indicate the sheath edge (i.e., the boundary between the sheath 238 and the quasi-neutral region of plasma in the chamber 210). After a short stabilization time, the initial transient settles to the steady-state for plasma 230 and the sheath 238 is established.

The plasma 230 comprises the cooler first plasma 234 and the heated second plasma 236. As mentioned above, the electron temperature of the second plasma 236 (Tₑ₂) is greater than that of the first plasma 234 (Tₑ₁). The second plasma 236 (which includes the heating zone 232) occupies the second region 228 except for the volume taken by the sheath 238 above and below the second plasma 236. The second plasma 236, having the higher electron temperature, Tₑ₂, is the annular heated plasma, mentioned above. The first plasma 234, having the lower electron temperature, Tₑ₁, is the remaining cooler portion of the plasma 230.

Although we are referring to Tₑ₁ and Tₑ₂ as discrete numbers, it is understood that the electron temperature does not change abruptly with position, i.e., Tₑ₁ and Tₑ₂ are profiles of electron temperature in the first plasma 234 and the second plasma 236, respectively. In the vertical direction, Tₑ₁ and Tₑ₂ are fairly uniform. Laterally, the higher electron temperature in the second plasma 236 transitions to the lower value in the first plasma 234 over a short distance. The lateral change of the electron temperature defining the spatially distinct first plasma 234 and second plasma 236 may be achieved by applying a DC magnetic field, as explained in further detail below.

The topology of the magnetic flux that passes through a region where a magnetic field is present is often visualized by constructing tubular shapes within the region, referred to as magnetic flux tubes. A flux tube is constructed such that, at every point on any side of the flux tube, the normal to the side passing through that point is also normal to the field line passing through that point or, equivalently, the sides of the magnetic flux tube everywhere is parallel to the magnetic field lines. All the field lines passing through a cross-section inside a flux tube remain inside, and not one of the field lines outside the flux tube ever enters the flux tube. If the field is an idealized uniform field, for example, the vertical DC magnetic field, B, in the cross-sectional view of apparatus 200 in FIG. 2, then the magnetic field lines are equally spaced vertical lines, as indicated by a group of dashed vertical arrows in FIG. 2. In a uniform field, all parallel cross-sections, (e.g., all horizontal cross-sections) of a flux tube have the same size and shape. But, in general, the size and shape of two parallel cross-sections may be different in order to accommodate all the magnetic flux flowing through one cross-section to flow through the other. The extent of a cross-section across a flux tube may be described by a width dimension defined here as the farthest distance between any two points on its boundary. By construction, there is no magnetic flux flowing across any side of a magnetic flux tube, thus, the magnetic flux flowing through any cross-section of the flux tube is the same, irrespective of its location or orientation.

From the above description of a flux tube it is clear that, for every specific planar bounded area in a magnetic field (e.g., the magnetic field, B, in FIG. 2), there is a unique flux tube that intercepts that area, by which we mean that the specific planar bounded area is a cross-section of the unique flux tube, and the boundary of that bounded area is a closed curve on the sides of the respective flux tube. As explained further below, the flux tube that intercepts the hold area 218A, referred to here as the central flux tube, and its widths at locations above the substrate holder 218 are of particular interest. A width dimension of the central flux tube, at an arbitrary location, is defined (in this disclosure) to be the width of the horizontal cross-section of the central flux tube at that location. For example, at the horizontal top surface of the substrate holder 218, the width of the central flux tube is the width of the hold area 218A.

In the idealized configuration of the DC magnetic field, B, the central flux tube is a vertical cylinder coincident with the first region 226, which has a width equal to the width of the hold area 218A. At the plane of the ceiling, the central flux tube intercepts a circular area in the conductive cover 212. In other words, the hold area 218A on the top surface of the substrate holder 218 is mapped by the central flux tube to the circular area in the conductive cover 212 intercepted by the central flux tube. The conductive cover 212 is wider than the hold area, hence the conductive cover 212 extends beyond the central flux tube up to an inner edge of the dielectric window 214. Within a depth directly below the dielectric window 214, is the heating zone 232 in the second region 228, as described above. Noting that the second region 228 is spaced from the first region 226 by the width of the third region 227 and that the first region 226 is wider than the substrate 202 (the substrate being positioned to be within the first region 226), it is apparent that, for this configuration of the magnetic field, the substrate 202 is inside the central flux tube, and the heating zone 232 is outside the central flux tube during processing. Indeed, the annular third region 227 between the first region 226 and the second region 228 provides a margin for error.

As explained in further detail below, in the time between collisions, mobile electrons in a magnetic field are driven by the field to spiral along the magnetic field lines. Since free electrons in the plasma are being heated (i.e., energized) by the AC electric field in the heating zone, on the average, more “hot” electrons are directed along those field lines that pass through the heating zone 232. Clearly, it is undesirable to have hot electrons directed toward the substrate 202 when, as mentioned above, it is desirable to lower the electron temperature in the region above the substrate 202 in order to reduce the ion angular spread. Hence, it is desirable for any embodiment to ensure that none of the magnetic field lines passing through its heating zone intersects the substrate 202. As mentioned above, this has been achieved in the apparatus 200 in FIG. 2 by configuring a magnet 240 to generate the DC magnetic field, B, where the heating zone 232 falls outside the central flux tube. Since a magnetic field line outside a flux tube never enters the flux tube, no field line from the heating zone 232 intersects the substrate 202, which is inside the central flux tube.

The DC magnetic field, in the embodiments described in this disclosure, is axisymmetric around the central axis of the chamber 210, which is the common central axis of the conductive cover 212, the dielectric window 214, and the hold area 218A. The topology of the DC magnetic field may be adjusted by adjusting the configuration of a magnet, such as its geometry. In some embodiments, the magnet may comprise several magnet elements. The magnet may include a permanent magnet, an electromagnet, or a combination thereof. The magnitude and topology of magnetic fields generated by electromagnets may be adjusted by adjusting a configuration of electrical currents that magnetize the electromagnet, in addition to adjusting its geometry. Hence, the use of electromagnets provides an advantage of electrically adjusting the DC magnetic field between different process steps or during a process.

We have selected the vertical magnetic field configuration to describe the inventive aspects of this invention because of the simplicity of this embodiment. The idealized uniform vertical magnetic field, B, in the configuration of apparatus 200, illustrated in FIG. 2, is by example only and should not be considered as limiting to the present invention.

In other embodiments, other axisymmetric magnetic field configurations may be used with the constraint that, in the region of the chamber above the substrate holder 218, the central flux tube excludes the heating zone 232. In some embodiments, this constraint may be met by configuring the magnet to generate a magnetic field, where, in all horizontal planes between the substrate holder 218 and the ceiling, the width of the central flux tube (i.e., a maximum width of the central flux tube) is less than or equal to the width of the hold area 218A. Note that the dielectric window 214 is contiguous with the conductive cover 212 and, in this embodiment, the conductive cover 212 is wider than the hold area 218A, as described above. Thus, by constraining the maximum width of the central flux tube to the width of the hold area 218A, we retain the extra separation provided by the annular third region 227.

However, the constraint that the central flux tube excludes the heating zone 232 (as mentioned above) is also met if, in the region of the chamber above the substrate holder 218, the width of the central flux tube is constrained to be less than or equal to the width of the conductive cover 212. Thus, in some embodiments, the constraint may be relaxed to where, between the substrate holder 218 and the ceiling of the chamber 210, the maximum width of the central flux tube less than or equal to the width of the conductive cover 212 (instead of the width of the hold area 218A).

In some other embodiments, the constraint on the maximum width of the central flux tube may be further relaxed to allow, for example, a bulge in the central flux tube in some region of the chamber 210 above the substrate holder 218 and below the heating zone 232. In these embodiments, the relaxed constraint may be, simply, that a width of the central flux tube at the ceiling is less than or equal to a width of the conductive cover 212.

The relaxed constraints increase a likelihood of an overlap between the central flux tube and the toroidal heating zone 232, and thus, reduce an effectiveness of the DC magnetic field in lowering the electron temperature of the plasma over the substrate 202 (e.g., the first plasma 234) relative to the plasma below the dielectric window 214 (e.g., the second plasma 236). However, even with the relaxed constraints the magnet may be configured to provide a geometry of the DC magnetic field such that, on average, the number of hot electrons entering the central flux tube is low enough to maintain a desired difference in electron temperatures between the hotter second plasma and the cooler first plasma.

A configuration of the magnet may be designed to achieve appropriate DC magnetic fields for a range of plasma parameters that are likely to be encountered during operation of the plasma processing apparatus. The configuration may include selection and placement of multiple magnets, the electrical currents flowing through coils of electromagnets, and the like. Generally, the design process involves experimental measurements and theoretical calculations of the DC and AC EM fields inside the chamber 210, including numerical simulations performed with computer-aided-design (CAD) tools. The experiments and calculations may span a parameter space that comprises not only those that are related to the configuration of the magnet (e.g., geometry of the magnet and the electrical current in an electromagnet) but also relevant plasma parameters that affect the electron temperatures of plasma in the chamber 210. For example, the parameter space may include those that affect the skin depth, hence the depth of the toroidal heating zone 232. Thus, embodiments that allow a portion of the central flux tube to be wider than the conductive cover 212 may be designed using CAD tools to ensure that, between the ceiling and the depth directly below the dielectric window within which the heating zone 232 is located, the central flux tube is as wide as or narrower than the conductive cover 212. As mentioned above, the depth of the toroidal heating zone 232 is about double the skin depth of the plasma below the dielectric window 214.

Typically, in an electromagnet, a magnetic field is generated by flowing current through a set of conductive loops coiled around a cylinder. In FIG. 2, the example embodiment of the magnet 240 comprises an electromagnet having a conductive wire shaped like a helix winding around the chamber 210 outside its boundary walls 216. As illustrated schematically in FIG. 2, the helix-shaped wire and the dielectric window 214 share a common central axis. When coupled to a DC current source, each turn of the helix is like a horizontal current loop, and the helical coil forms a set of such loops with equal current in each loop. As known to people skilled in the art, a substantially vertical DC magnetic field may be generated in the cylindrical chamber 210 by configuring the magnet 240 to have a length of the helix (the dimension along the vertical central axis) to be substantially greater than a diameter of the helix. Thus, vertically, the magnet 240 may extend from below the substrate holder 218 to above the dielectric window 214.

The example embodiment of the magnet 240, described above, is designed to generate the uniform magnetic field, B. However, this embodiment may be modified geometrically and electrically to generate other axisymmetric magnetic fields.

For example, the helical coil may be tapped at various vertical locations and coupled to various electrical circuit elements to configure the vertical profile of the current flowing in the turns of the coil, and the current profile may be engineered to flow less current in the turns near the bottom of the chamber 210 relative to the current flowing in the turns near the top of the chamber 210 by selecting appropriate circuit elements.

In another example, the single helical coil of the example embodiment of magnet 240 may be split into a set of vertically arranged helical coils, where each coil of the set of coils is coupled to its respective current source, such that the coils near the top of the chamber 210 carries more current relative to those near the bottom of the chamber 210.

An example of a geometrical modifications may be modifying the cylindrical helix of the example magnet 240 to a conical helix, where the conical helix has a diameter that increases from top to bottom.

Another example of a geometrical modifications may be reducing the length of the helical coil to a range in which the magnetic field lines deviates significantly from the vertical.

In some other embodiment, the magnet may comprise a permanent magnet. For example, a similarly oriented DC magnetic field B may be produced by configuring the permanent magnet to have one magnetic pole above the dielectric window 210 and an opposite magnetic pole below the substrate holder 218. In various embodiments, the magnet may be a magnet assembly having multiple magnets. In some embodiments, the magnet assembly may be a combination of permanent magnets and electromagnets. In the example apparatus 200, illustrated in FIG. 2, the magnet is disposed outside the chamber 210. In some other embodiment, the magnet may be placed inside the chamber 210.

In all these embodiments, the magnet is configured to generate a DC magnetic field in the chamber 210, where it is designed such that no portion of the heating zone 232 is included in the central flux tube; the central flux tube is the unique flux tube which intercepts the hold area 218A. In an embodiment, all horizontal planes between the substrate holder 218 and the ceiling, the width of the central flux tube is less than or equal to the width of the hold area 218A. The constraint that the width of the central flux tube is less than or equal to the width of the hold area 218A may be relaxed to restrict the maximum width of this portion of the central flux tube to be less than or equal to the width of the conductive cover 212.

The free electrons and ions generated in the second plasma 236 vertically below the dielectric window 214 experience the Lorentz force due to the DC magnetic field B. According to EM theory, the Lorentz force on a charged particle is its charge times a cross product of its velocity and the magnetic field. Thus, the Lorentz force is always directed perpendicular to the direction of the velocity of the particle and perpendicular to the direction of the local magnetic field. In the embodiments in this disclosure, the Lorentz force due to the applied DC magnetic field causes the charged particles of the plasma in the chamber 210 to gyrate in a spiral trajectory along a magnetic field line. A radius of the spiral, referred to as the Larmor radius, may be adjusted by adjusting a magnitude of the DC magnetic field, with the Larmor radius reducing with increasing magnetic field strength. Note that the Lorentz force does not change the kinetic energy of the charged particle or the component of its velocity parallel to the magnetic field line.

Consider a free electron of the second plasma 236 in the presence of the DC magnetic field B in FIG. 2. Between successive collisions, the Lorentz force would drive the free electron spiraling vertically toward the sheath 238. If it reaches the sheath 238, the high vertical electric field in the sheath 238 would reflect it back, and the Lorentz force would cause it to spiral back vertically toward the sheath 238 on the opposite side. In the absence of the DC magnetic field B, during the time between collisions, a fast-moving free electron with a high horizontal component of velocity may travel laterally a sufficient distance to exit the second plasma 236. By inhibiting such events, the DC magnetic field B retains more of the kinetic energy of the free electrons within the second plasma 236. Nevertheless, due to random collisions occurring in the second plasma 236, mostly with the large number of neutral particles, there is a net lateral diffusion of free electrons out of the second plasma 236.

In contrast, because of their much larger mass, ions have a large Larmor radius compared to free electrons. Consequently, for typical DC magnetic fields, the impact on ion motion is relatively small and may be ignored. Thus, ions in the second plasma 236 diffuse into the first plasma 234, unhindered by the presence of the DC magnetic field. Eventually, the ions, which flow into the first plasma 234, flow out to the substrate 202. However, the net DC current to the substrate 202 must equal zero since, generally, the substrate 202 is placed on an insulating surface. Accordingly, on average, equal fluxes of electrons and ions must flow out of the second plasma 236 into the first plasma 234 and, thence, to the substrate 202. As explained above, there is a lateral diffusion of electrons resulting from collisions with neutrals, and the ion and electron concentration profiles internal to the plasma get adjusted to establish a steady state in which the fluxes of electrons and ions are balanced.

As mentioned above, in all embodiments of this invention, the magnet is configured to generate the DC magnetic field such that the heating zone 232 falls outside the central flux tube. Thus, no magnetic field line inside the central flux tube can be traced to the heating zone 232 and, likewise, all magnetic field lines entering the heating zone 232 remain outside the central flux tube. It is noted that, in the example embodiment of the apparatus 200, the central flux tube contains the first plasma 234 and does not contain the second plasma 236.

When free electrons diffuse (from the second plasma 236) into the first plasma 234 they are inside the central flux tube. Hence, they are on a field line which does not trace back to the heating zone 232 and thus are no longer heated further by the electromagnetic fields. However, the free electrons continue to suffer inelastic collisions with neutrals that remove energy from them. As known to persons skilled in the art, higher energy free electrons undergo inelastic collision more frequently than lower energy electrons. Thus higher energy free electrons are preferentially cooled. It is noted here that the diffusion of free electrons across the magnetic field lines only occurs because of collisions. A certain fraction of those collisions being inelastic collisions, the very act of diffusing from the second plasma 236 into the first plasma 234 results in a loss of energy, particularly so for the higher energy free electrons.

On the other hand, free electrons which remain in the second plasma 236 may spiral up and down magnetic field lines that pass through the heating zone 232 (as explained above). By repeatedly passing through the heating zone 232 on each vertical round trip transit, the free electrons in the second plasma 236 are efficiently heated. Thus, the outer second plasma 236 (in the second region 228) is relatively hot, leaving the inner first plasma 234 (in the first region 226) relatively cool.

The diffusion fluxes of ions and free electrons from the second plasma 236 populates the first plasma 234, and the first plasma 234 supplies the respective vertical fluxes of ions and free electrons that reach the substrate 202. As explained above, the electron temperature, Tₑ₂, of the second plasma 236 is greater than Tₑ₁, the electron temperature of the first plasma 234.

The Larmor radius, on average, depends on electron temperature. Hence, a DC magnetic field strength may be selected based on an estimate of Tₑ₂ and a width of the dielectric window 214. In various embodiments, the magnet 240 may be configured to provide a magnitude of the DC magnetic field B from about 10 G to about 600 G. Accordingly, in various embodiments, a ratio of the lower electron temperature to the higher electron temperature, Tₑ₁:Tₑ₂, may be from about 0.01 to about 0.2.

The ions in the first plasma 234 that enter the pre-sheath and the sheath 238, get accelerated by the vertical electric field there and impinge on the substrate 202. In order to achieve a smaller spread in the ion angle distribution, it is desired that all the ions incident on the substrate 202 are coming from the first plasma 234, where the electron temperature, Tₑ₁, is relatively low. The magnet 240 is, thus, configured to generate the DC magnetic field B in the chamber 210, wherein all of the field lines of the DC magnetic field in the central flux tube are outside the heating region 232. Alternatively, the magnet 240 may be configured to generate the DC magnetic field B such that all of the field lines that pass through the heating region 232 bypass the hold area 218A. Otherwise, there is a possibility of charged particles from the “hotter” second plasma 236 to spiral along a magnetic field line of the DC magnetic field B and approach the substrate 202 in the hold area 218A.

The geometrical arrangement of the conductive cover 212, the dielectric window 214, and the hold area 218A is designed to keep a separation between the second region 228 and the substrate 202 in the hold area 218A. The width of hold area 218A is designated to be larger than the width of the substrate 202 and the first ring 218B is used to space the hold area 218A from the second ring 218C (the area vertically under the dielectric window 214). This arrangement makes it extremely unlikely for any part of the substrate 202 to be positioned in a region where the electron temperature is relatively high. This further ensures that the ions in a portion of the sheath 238 adjacent vertically above the substrate 202 are arriving from the cooler first plasma 234. In other words, as illustrated in FIG. 2, the portion of the sheath 238 that is in contact with the substrate 202 is contiguous with the cooler first plasma 234, as is desired for a better collimated ion flux to be incident on the substrate 202 (because the electron temperature, Tₑ₁, is lower). The portion of the sheath 238 that is contiguous with the second plasma 236 and is having the higher electron temperature, Tₑ₂, is not in contact with the substrate 202.

As mentioned above, the example embodiment of the plasma processing apparatus 200 is configured to operate in an ICP configuration, where the AC electric field in the heating zone 232 is oriented horizontally. However, some capacitive coupling may occur due to voltage differences between the antenna 220 and the plasma in the chamber 210 directly below the dielectric window 214. Capacitive coupling during plasma processing is undesirable for the embodiments described in this disclosure because it results in a vertical component of the AC electric field that may raise Tₑ₁, as explained herein. The vertical component of the AC electric field would cause the entire horizontal sheath edge of the sheath 238 to oscillate in response to the oscillating vertical voltage drop caused by vertical component of the AC electric field, including the sheath edge of the sheath 238 above the top surface of the substrate 202. A movement of the sheath edge above the substrate 202 would cause an undesirable vertical electron current due to the free electrons responding to the oscillating electric field near the sheath edge. This electron current may undesirably heat the free electrons in the first plasma 234. Therefore, it may be beneficial to suppress parasitic capacitive coupling during the plasma processing. Typically, in a chamber configured for ICP processing, a Faraday shield is used to suppress such parasitic capacitive coupling. In some embodiments, the Faraday shield 250 may be coupled to a reference potential, referred to as ground. As illustrated in FIG. 2, a Faraday shield 250 (shown schematically) has been inserted in the plasma processing chamber 210 adjacent below the dielectric window 214. The Faraday shield 250, interposed between the antenna 220 and the heating zone 232, may be a metal structure comprising slits in a thin metal plate. Various designs may be used; for example, the Faraday shield 250 may comprise a thin copper plate with a pattern of slits, for example, a radial pattern of slits extending across the edges of the dielectric window. The slits allow EM power to couple inductively to the heating zone 232 in the chamber 210, while attenuating a vertical component of the AC electric field. The dimensions of the slit determine a frequency dependent attenuation of the vertical AC electric field provided by the shield. Generally, the attenuation is greater for AC EM fields having a lower frequency.

The plasma processing chamber 210, illustrated in FIG. 2 is coupled to a gas flow system configured to flow a discharge gas at low pressure through the chamber 210. A gas inlet 262 and a gas outlet 264 coupling the chamber 210 to the gas flow system are illustrated schematically in FIG. 2. The gas outlet 264 is coupled to a vacuum pump 266 of the gas flow system. The discharge gas, introduced in the chamber 210 through the gas inlet 262, may be a gaseous mixture comprising reactants, diluents, and additives. The gas pumped out through the gas outlet 264 may further include volatile byproducts produced in the chamber 210 during processing. Inside the chamber 210, gas is directed to flow from the gas inlet 262, over the substrate 202, and out through the gas outlet 264. In addition, the gas flow system may include gas canisters, flow lines, throttle valves, gas flow sensors and controllers, and the like.

For some plasma processes, where the pressure in the chamber 210 may be controlled to be very low (e.g., about 0.1 Pa to 10 Pa), some capacitive coupling may be desired for igniting plasma. Thus, in some embodiments, the Faraday shield 250 may be designed to facilitate igniting plasma using power from AC EM fields produced by the antenna 220 at a first frequency by allowing more capacitive coupling relative to the AC EM fields at a second frequency, which may be the operating frequency during plasma processing. Once plasma is ignited, the apparatus may be adjusted to couple power from AC EM fields produced by the antenna 220 at the second frequency, where the second frequency is less than the first frequency. The higher first frequency is used to ignite plasma since the Faraday shield is more transparent to a vertical AC electric field at a higher frequency.

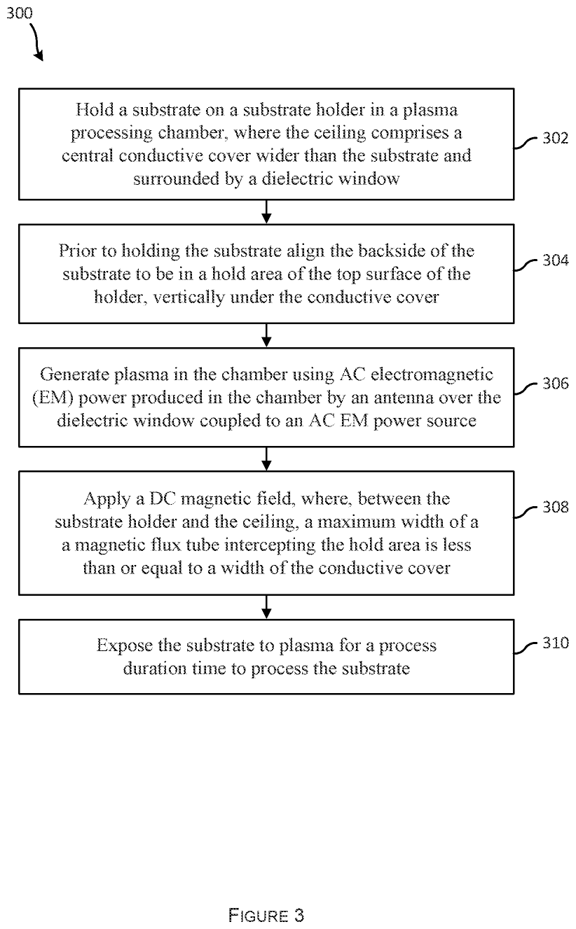

FIG. 3 illustrates a flow chart summarizing a method 300 for plasma processing using, for example, the apparatus 200, described above with reference to FIG. 2.

As indicated in box 302, the method 300 comprises holding a substrate (e.g., substrate 202 in FIG. 2) on a substrate holder (e.g., substrate holder 218 in FIG. 2) in a plasma processing chamber (e.g., chamber 210 in FIG. 2) having a ceiling comprising a central conductive cover (e.g., the conductive cover 212 in FIG. 2) that is wider than the substrate and surrounded by a dielectric window (e.g., the dielectric window 214 in FIG. 2).

As indicated in box 304, prior to holding the substrate, the backside of the substrate is aligned to be in a hold area (e.g., the hold area 218A indicated in FIG. 2) of the top surface of the holder vertically under the conductive cover.

While holding the substrate, the method 300 comprises generating plasma in the chamber using AC EM power produced in the chamber by an antenna (e.g., antenna 220 in FIG. 2) over the dielectric window, where the antenna is coupled to an AC EM power source (e.g., the AC EM power source 222 in FIG. 2), as indicated in box 306.

In box 308 of the method 300, a DC magnetic field is applied using a magnet (e.g., magnet 240 in FIG. 2), where, between the substrate holder and the ceiling, a maximum width of a central flux tube is less than or equal to a width of the conductive cover, the central flux tube being a magnetic flux tube intercepting the hold area.

In box 310 of the method 300, the substrate is exposed to the plasma in the chamber for a process duration time to process the substrate.

Example embodiments of the invention are described below. Other embodiments can also be understood from the entirety of the specification as well as the claims filed herein.

Example 1. An apparatus for plasma processing a substrate, where the apparatus includes a plasma processing chamber having a ceiling including a central conductive cover surrounded by a dielectric window, the conductive cover being wider than the substrate; a substrate holder configured to hold the substrate in the chamber, a backside of the substrate being aligned to be inside a hold area of a horizontal top surface of the holder, the hold area being an area under the conductive cover; disposed over the dielectric window, an antenna configured to couple AC electromagnetic (EM) power from an AC EM signal to plasma in the chamber, the AC EM power being absorbed in a heating zone located within a depth directly below the dielectric window; and a magnet configured to generate a DC magnetic field in the chamber, where a width of a central flux tube at the ceiling is less than or equal to a width of the conductive cover, the central flux tube being a magnetic flux tube intercepting the hold area.

Example 2. The apparatus of example 1, where, between the ceiling and the depth directly below the dielectric window within which the heating zone is located, the central flux tube is as wide as or narrower than the conductive cover.

Example 3. The apparatus of one of examples 1 or 2, where, between the substrate holder and the ceiling, the central flux tube is as wide as or narrower than the conductive cover.

Example 4. The apparatus of one of examples 1 to 3, where the antenna is configured to receive the AC EM signal from a radio frequency (RF) power supply or a microwave frequency power supply, the AC EM signal having a center frequency between 100 kHz and 10 GHz.

Example 5. The apparatus of one of examples 1 to 4, where the antenna is configured to inductively couple the AC EM power to the plasma in the chamber.

Example 6. The apparatus of one of examples 1 to 5, where the antenna includes a conductor shaped like a planar coil, the planar coil shaped antenna and the dielectric window sharing a common central axis.

Example 7. The apparatus of one of examples 1 to 6, where the antenna is a resonator configured to have a resonant frequency tuned to match a center frequency of the AC EM signal.

Example 8. The apparatus of one of examples 1 to 7, further including a Faraday shield including a conductive layer with a pattern of slits, the shield being disposed in the chamber adjacent below the dielectric window.

Example 9. The apparatus of one of examples 1 to 8, where a portion of the magnet is disposed in the chamber.

Example 10. The apparatus of one of examples 1 to 9, where the magnet includes a multiplicity of electromagnets, each electromagnet of the multiplicity of electromagnets including a conductive wire shaped like a helix, the helix-shaped wire and the dielectric window sharing a common central axis, and where a first electromagnet of the multiplicity of electromagnets is configured to conduct a first DC current and a second electromagnet of the multiplicity of electromagnets is configured to conduct a second DC current different from the first DC current.

Example 11. The apparatus of one of examples 1 to 10, where the magnet includes an electromagnet including a conductive wire shaped like a helix, the helix-shaped wire and the dielectric window sharing a common central axis.

Example 12. The apparatus of one of examples 1 to 11, where the magnet includes a permanent magnet.

Example 13. The apparatus of one of examples 1 to 12, where the chamber further includes a gas inlet and a gas outlet coupled to a gas flow system configured to flow a discharge gas through the chamber.

Example 14. An apparatus for plasma processing a substrate, where the apparatus includes a plasma processing chamber having a ceiling including a central conductive cover surrounded by a dielectric window, the conductive cover being wider than the substrate; a substrate holder configured to hold the substrate in the chamber, a backside of the substrate being aligned to be inside a hold area of a horizontal top surface of the holder, the hold area being an area under the conductive cover; disposed over the dielectric window, an antenna configured to produce AC electric and magnetic fields in a plasma generated in the chamber, the AC electric field being in a second region laterally separated from a first region of the chamber, the first region being a central tube bounded by and including the hold area at the bottom and bounded by the conductive cover at the top; and a magnet configured to generate a DC magnetic field in the chamber, where, between the substrate holder and the ceiling, a maximum width of a central flux tube is less than or equal to a width of the conductive cover, the central flux tube being a magnetic flux tube intercepting the hold area.

Example 15. The apparatus of example 14, where the conductive cover, the dielectric window, the hold area, and the first region share a common central axis.

Example 16. The apparatus of one of examples 14 or 15, where the magnet is outside the chamber.

Example 17. The apparatus of one of examples 14 to 16, where the conductive cover is wider than the hold area.

Example 18. A method for plasma processing, where the method includes holding a substrate on a horizontal top surface of a substrate holder in a plasma processing chamber having a ceiling including a central conductive cover surrounded by a dielectric window, the conductive cover being wider than the substrate; prior to holding the substrate, aligning its backside to be inside a hold area of the top surface of the holder, the hold area being an area under the conductive cover; generating plasma in the chamber using power from AC electromagnetic (EM) fields produced in the chamber by an antenna disposed over the dielectric window, the antenna being coupled to an AC EM power source; applying a DC magnetic field with a magnet configured to generate the DC magnetic field in the chamber, where, between the substrate holder and the ceiling, a maximum width of a central flux tube is less than or equal to a width of the conductive cover, the central flux tube being a magnetic flux tube intercepting the hold area; and exposing the substrate to plasma for a process duration time to process the substrate.

Example 19. The method of example 18, where applying the DC magnetic field includes: forming a first plasma in a central portion above the hold area and a second plasma in an annular region below the dielectric window and around the central portion, the first plasma having a first electron temperature and the second plasma having a second electron temperature greater than the first electron temperature.

Example 20. The method of one of examples 18 or 19, further including: having a Faraday shield disposed in the chamber adjacent below the dielectric window, the Faraday shield being configured to attenuate a vertical component of an AC electric field of the AC EM fields produced by the antenna, the attenuation being greater for AC EM fields having a lower frequency.

Example 21. The method of one of examples 18 to 20, where generating the plasma includes: igniting plasma using power from the AC EM fields produced by the antenna, the AC EM fields having a first frequency; and coupling power from the AC EM fields to the plasma, the AC EM fields being produced by the antenna in a heating zone located within a depth directly below the dielectric window, the radiation having a second frequency less than the first frequency.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An apparatus for plasma processing a substrate, the apparatus comprising:
a plasma processing chamber having a ceiling comprising a central conductive cover surrounded by a dielectric window, the conductive cover being wider than the substrate;
a substrate holder configured to hold the substrate in the chamber, a backside of the substrate being aligned to be inside a hold area of a horizontal top surface of the holder, the hold area being an area under the conductive cover;
disposed over the dielectric window, an antenna configured to couple alternating current (AC) electromagnetic (EM) power from an AC EM signal to plasma in the chamber, the AC EM power being absorbed in a heating zone located within a depth directly below the dielectric window; and
a magnet configured to generate a DC magnetic field in the chamber, wherein a width of a central flux tube at the ceiling is less than or equal to a width of the conductive cover, the central flux tube being a magnetic flux tube intercepting the hold area.

2. The apparatus of claim 1, wherein, between the ceiling and the depth directly below the dielectric window within which the heating zone is located, the central flux tube is as wide as or narrower than the conductive cover.

3. The apparatus of claim 1, wherein, between the substrate holder and the ceiling, the central flux tube is as wide as or narrower than the conductive cover.

4. The apparatus of claim 1, wherein the antenna is configured to inductively couple the AC EM power to the plasma in the chamber.

5. The apparatus of claim 1, wherein the antenna comprises a conductor shaped like a planar coil, the planar coil shaped antenna and the dielectric window sharing a common central axis.

6. The apparatus of claim 1, wherein the antenna is a resonator configured to have a resonant frequency tuned to match a center frequency of the AC EM signal.

7. The apparatus of claim 1, further comprising a Faraday shield comprising a conductive layer with a pattern of slits, the shield being disposed in the chamber adjacent below the dielectric window.

8. The apparatus of claim 1, wherein a portion of the magnet is disposed in the chamber.

9. The apparatus of claim 1, wherein the magnet comprises a multiplicity of electromagnets, each electromagnet of the multiplicity of electromagnets comprising a conductive wire shaped like a helix, the helix-shaped wire and the dielectric window sharing a common central axis, and
wherein a first electromagnet of the multiplicity of electromagnets is configured to conduct a first DC current and a second electromagnet of the multiplicity of electromagnets is configured to conduct a second DC current different from the first DC current.

10. The apparatus of claim 1, wherein the magnet comprises an electromagnet comprising a conductive wire shaped like a helix, the helix-shaped wire and the dielectric window sharing a common central axis.

11. The apparatus of claim 1, wherein the magnet comprises a permanent magnet.

12. The apparatus of claim 1, wherein the chamber further comprises a gas inlet and a gas outlet coupled to a gas flow system configured to flow a discharge gas through the chamber.

13. An apparatus for plasma processing a substrate, the apparatus comprising:
a plasma processing chamber having a ceiling comprising a central conductive cover surrounded by a dielectric window, the conductive cover being wider than the substrate;
a substrate holder configured to hold the substrate in the chamber, a backside of the substrate being aligned to be inside a hold area of a horizontal top surface of the holder, the hold area being an area under the conductive cover;
disposed over the dielectric window, an antenna configured to produce AC electric and magnetic fields in a plasma generated in the chamber, the AC electric field being in a second region laterally separated from a first region of the chamber, the first region being a central tube bounded by and including the hold area at the bottom and bounded by the conductive cover at the top; and
a magnet configured to generate a DC magnetic field in the chamber, wherein, between the substrate holder and the ceiling, a maximum width of a central flux tube is less than or equal to a width of the conductive cover, the central flux tube being a magnetic flux tube intercepting the hold area.

14. The apparatus of claim 13, wherein the conductive cover, the dielectric window, the hold area, and the first region share a common central axis.

15. The apparatus of claim 13, wherein the magnet is outside the chamber.

16. The apparatus of claim 13, wherein the conductive cover is wider than the hold area.

17. A method for plasma processing comprising:
holding a substrate on a horizontal top surface of a substrate holder in a plasma processing chamber having a ceiling comprising a central conductive cover surrounded by a dielectric window, the conductive cover being wider than the substrate;
prior to holding the substrate, aligning its backside to be inside a hold area of the top surface of the holder, the hold area being an area under the conductive cover;
generating plasma in the chamber using power from AC electromagnetic (EM) fields produced in the chamber by an antenna disposed over the dielectric window, the antenna being coupled to an AC EM power source;
applying a DC magnetic field with a magnet configured to generate the DC magnetic field in the chamber, wherein, between the substrate holder and the ceiling, a maximum width of a central flux tube is less than or equal to a width of the conductive cover, the central flux tube being a magnetic flux tube intercepting the hold area; and
exposing the substrate to plasma for a process duration time to process the substrate.

18. The method of claim 17, wherein applying the DC magnetic field comprises:
forming a first plasma in a central portion above the hold area and a second plasma in an annular region below the dielectric window and around the central portion, the first plasma having a first electron temperature and the second plasma having a second electron temperature greater than the first electron temperature.

19. The method of claim 17, further comprising: having a Faraday shield disposed in the chamber adjacent below the dielectric window, the Faraday shield being configured to attenuate a vertical component of an AC electric field of the AC EM fields produced by the antenna, the attenuation being greater for AC EM fields having a lower frequency.

20. The method of claim 19, wherein generating the plasma comprises:
igniting plasma using power from the AC EM fields produced by the antenna, the AC EM fields having a first frequency; and
coupling power from the AC EM fields to the plasma, the AC EM fields being produced by the antenna in a heating zone located within a depth directly below the dielectric window, the radiation having a second frequency less than the first frequency.
